(19) United States
(12) Patent Application Publication
(10) Pub. No.: US 2009/0302465 A1
(43) Pub. Date: Dec. 10, 2009

(54) DIE REARRANGEMENT PACKAGE STRUCTURE AND METHOD THEREOF

(76) Inventor: Cheng-Tang HUANG, Hsinchu city (TW)

Correspondence Address: SINORICA, LLC, 2275 Research Blvd., Suite 500, ROCKVILLE, MD, 20850, US

(21) Appl. No.: 12/330,764

(22) Filed: Dec. 9, 2008

(30) Foreign Application Priority Data
Jun. 5, 2008 (TW) 097120848

(51) Int. Cl. H01L 21/50; H01L 21/768; H01L 23/498

(52) U.S. Cl. 257/737; 438/106; 438/613; 257/E21.499; 257/E21.595; 257/E23.068

(57) ABSTRACT

A die rearrangement package structure is provided and includes a die; an encapsulated structure is covered around the four sides of the die to expose the active surface and the reverse side of the die; a patterned protective layer is formed on the encapsulated structure and the active surface of the die, and the pads is to be exposed; one end of fan-out patterned metal layer is electrically connected the pads and other end is extended to cover the patterned protective layer; patterned second protective layer is provided to cover the patterned metal layer to expose the portions surface of the patterned metal layer; patterned UBM layer is formed on the exposed surface of the patterned metal layer; and a conductive component is formed on the patterned UBM layer, and electrically connected the patterned metal layer.

### BACKGROUND OF THE INVENTION

1. Field of the Invention

The present invention is related to a package structure and method thereof, and more particularly, is related to a die rearrangement package structure and method thereof by using a RDL.

2. Description of the Prior Art

The technology development in semiconductor is very fast, the microlize semiconductor dice is needed to have more functions therein. Thus, the microlize semiconductor dice needs to have more I/O pads within very tiny area, and the density of the pins is increased. Therefore, the conventional lead frame package technology is not good enough for high density pins, and a Ball Grid Array (BGA) package technology is developed. The BGA package technology is able to package the dice with high density pins and the solder ball is not easy to be damaged.

Because the 3C products, such as cell phone, portable digital assistant (PDA), or IPOD, are become more and more popular, the system die has to install in a tiny space. In order to solve this problem, a wafer level package (WLP) is invented. The WLP package can be done before the wafer is sawed into several dice. The U.S. Pat. No. 5,323,051 disclosed this kind of WLF package technology. However, when the number of the pads on the active surface of the dice is increased and the interval between the pads is too small, the signal in the dice will be overlapped or interrupted and the reliability of the package is decrease because of the small interval of the dice. Therefore, when the die is become smaller and smaller, the package technologies described above are not able to satisfy.

In order to solve the problem described above, U.S. Pat. No. 7,196,408 disclosed a package method that the wafer is done the testing and the sawing procedure in the semiconductor process and the good dice are put in another carrier board to do the package process. Therefore, those relocated dice are able to have a large interval and the pads on the dice can be arranged well. The fan-out technology is used and the problem of the small interval to cause the signal overlapped and interrupted can be solved.

However, in order to let the semiconductor die to have a smaller and thinner package structure, the wafer will do a thinning process, such as backside lapping, to thin the wafer in 2˜20 mil before sawing the wafer. Then, those dice will put on another carrier board and form into an encapsulated structure by a molding method. Because the die is very thin, the package structure is also very thin. When the package structure is moved from the substrate, the stress from the package structure itself will let the package structure bend over and the difficulty of the sawing process is increased.

Besides, after sawing the wafer, when the dice are relocated in another substrate, which is larger than the original one, by a pick and place device, the dice are moved over and the active surface of the dice is stuck on the carrier board by a flip-flop method. During the move over process, the dice are easy to tilt and cause displacement, such as tile more than 5 mm. Therefore, the dice are not able to locate correctly and the solder ball process is not able to locate at the right position and the reliability of the package structure is decreased.

### SUMMARY OF THE INVENTION

According the problems described in prior art, the main object of the present invention is to provide a carrier board with a package structure formed thereon. Because of the package structure, the dice are able to relocate on another carrier board, and each of the dice is able to accurately locate at the desired position.

Another object of the present invention is to provide a die rearrangement package method and the method is able to cut the 12 inches wafer to be a lot of dies and the dies are relocated on 8 inches wafer substrate. Therefore, the 8 inches wafer package equipment can use to do the 12 inches package work without rebuilding new 12 inches package equipment.

The other object of the present invention is to provide a die rearrangement package method to package the known good die to save the package materials and reduce the package cost.

According to the objects described above, the present invention also provides a die rearrangement package method, comprising: providing a carrier board, and the carrier board includes a top surface and a reverse surface; forming an encapsulated structure on the top surface of the carrier board and the encapsulated structure includes an opening formed on the top surface of the carrier board and exposed on a portion of the top surface of the carrier board; adhering a die on a portion of the exposed top surface of the carrier board and an active surface of the die is faced up, and the active surface includes a plurality of pads, a reverse surface of the die is adhered on a portion of the exposed top surface of the carrier board by an adhesive layer; forming a patterned first protective layer on the encapsulated structure and the patterned first protective layer is covered on the active surface of the die and exposes a portion of the top surface of the carrier board; forming a plurality of fan-out patterned metal leads, and one end of the metal lead is electrically connected to the pads on the active surface of the die; forming a patterned second protective layer, and the patterned second protective layer is covered on the fan-out patterned metal lead and exposes a portion of fan-out surface extended from the edge of the active surface of the die; forming a plurality of patterned UBM layer on the portion of fan-out surface extended from the edge of the active surface of the die and the patterned UBM layer is electrically connected to the metal lead; forming a plurality of conductive elements formed on the patterned UBM layer and electrically connected to the metal lead by the patterned UBM layer; and removing the carrier board to form a die package structure.

According to the objects described above, the present invention also provides a die rearrangement package method, comprising: providing a carrier board, and the carrier board includes a top surface and a reverse surface; forming an encapsulated structure on the top surface of the carrier board and the encapsulated structure includes a plurality of openings formed on the top surface of the carrier board and exposed on a portion of the top surface of the carrier board; adhering a plurality of dice on a portion of the exposed top surface of the carrier board and an active surface of the dice are faced up, and the active surface includes a plurality of pads, a reverse surface of each of the dice is adhered on a portion of the exposed top surface of the carrier board by an adhesive layer; forming a patterned first protective layer on the encapsulated structure and the patterned first protective layer is covered on the active surface of the die and exposes a portion of the top surface of the carrier board; forming a plurality of fan-out patterned metal leads, and one end of the metal lead is electrically connected to the pads on the active surface of the die; forming a patterned second protective layer, and the patterned second protective layer is covered on the fan-out patterned metal lead and exposes a portion of fan-out surface extended from the edge of the active surface of the die; forming a plurality of patterned UBM layer on the portion of fan-out surface extended from the edge of the active surface of the die and the patterned UBM layer is electrically connected to the metal lead; forming a plurality of conductive elements formed on the patterned UBM layer and electrically connected to the metal lead by the patterned UBM layer; and removing the carrier board to form a die package structure.

According to the objects described above, the present invention also provides a die including an active surface with a plurality of pads and a reverse surface with an adhesive layer; a die including an active surface with a plurality of pads and a reverse surface with an adhesive layer; an encapsulated structure, which is covered around four sides of the die to expose the active surface and the reverse surface of the die; a patterned first protective layer, which is formed on one surface of the encapsulated structure and covered on the active surface of the die, and the pads are exposed; a plurality of fan-out patterned metal lead, and one end of the metal lead is electrically connected to the pads on the active surface of the die; a patterned second protective layer covered over the fan-out patterned metal lead and exposing a portion of fan-out surface extended from the edge of the active surface of the die; a plurality of patterned UBM layer formed on the portion of fan-out surface extended from the edge of the active surface of the die; a plurality of conductive elements formed on the patterned UBM layer and electrically connected to the metal lead by the patterned UBM layer.

According to the objects described above, the present invention also provides a die including an active surface with a plurality of pads and a reverse surface with an adhesive layer; a plurality of dice and each of the dice includes an active surface with a plurality of pads and a reverse surface with an adhesive layer; an encapsulated structure, which is covered around four sides of the dice to expose the active surface and the reverse surface of the die; a plurality of patterned first protective layers, which are formed on one surface of the encapsulated structure and covered on the active surface of the dice, and the pads are exposed; a plurality of fan-out patterned metal lead, and one end of the metal lead is electrically connected to the pads on the active surface of the die; a plurality of patterned second protective layer covered over the fan-out patterned metal lead and exposing a portion of fan-out surface extended from the edge of the active surface of the die; a plurality of patterned UBM layer formed on the portion of fan-out surface extended from the edge of the active surface of the die; a plurality of conductive elements formed on the patterned UBM layer and electrically connected to the metal lead by the patterned UBM layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a sectional view showing that the package structure on the substrate;

FIG. 2 is a sectional view showing that the dice are disposed on the package structure of the substrate;

FIG. 3 and FIG. 4 are sectional views showing that a lot of patterned first protective layers are formed on the package structure;

FIG. 5 is a sectional view showing that the metal layer is formed on the first protective layer and pads;

FIG. 6 is a sectional view showing that the patterned metal lead is formed on the package structure and the pads of the dice;

FIG. 7 and FIG. 8 are views showing that a lot of patterned second protective layers are formed on the fan-out patterned metal leads;

FIG. 9 is a sectional view showing that a lot of patterned UBM layer are formed on the surface on the other end of the fan-out patterned metal leads;

FIG. 10 is a sectional view showing that the conductive elements are formed on the patterned UBM layer;

FIG. 11 is a sectional view showing that the single die package structure is formed;

FIG. 12 is a top view showing that a plurality of dice with different functions and different sizes to formed a system-in-package (SIP);

FIG. 13 is a view showing that the dice with different sizes and different functions are disposed on the carrier board with package structure;

FIGS. 14 and 15 are sectional views showing that a lot of patterned first protective layers are formed;

FIG. 16 is a sectional view showing that the metal layer is formed on the patterned first protective layers;

FIG. 17 is a sectional view showing that the patterned metal lead is formed on the patterned first protective layer;

FIGS. 18 and 19 are views showing that a lot of patterned second protective layer are formed on the fan-out patterned metal leads; and

FIG. 20 is a view showing that a lot of patterned UBM layers are formed on the surface of the other end of the metal leads; and

FIG. 21 is a view showing that a package structure is formed after removing the carrier board in accordance with the present invention.

### DESCRIPTION OF THE PREFERRED EMBODIMENT

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components.

In the present semiconductor package method, the wafer done with the front end process will do a thinning process, such as thinning the wafer to be 2˜20 mil thick. Then, a sawing process is performed to saw the wafer to be a plurality of dies and a pick and place apparatus is used to relocate the die in another substrate. Obviously, the dice in the new carrier board able to have an interval larger than the die. Therefore, those die are able to have wider intervals and the pads on the dice are able to reorganize well.

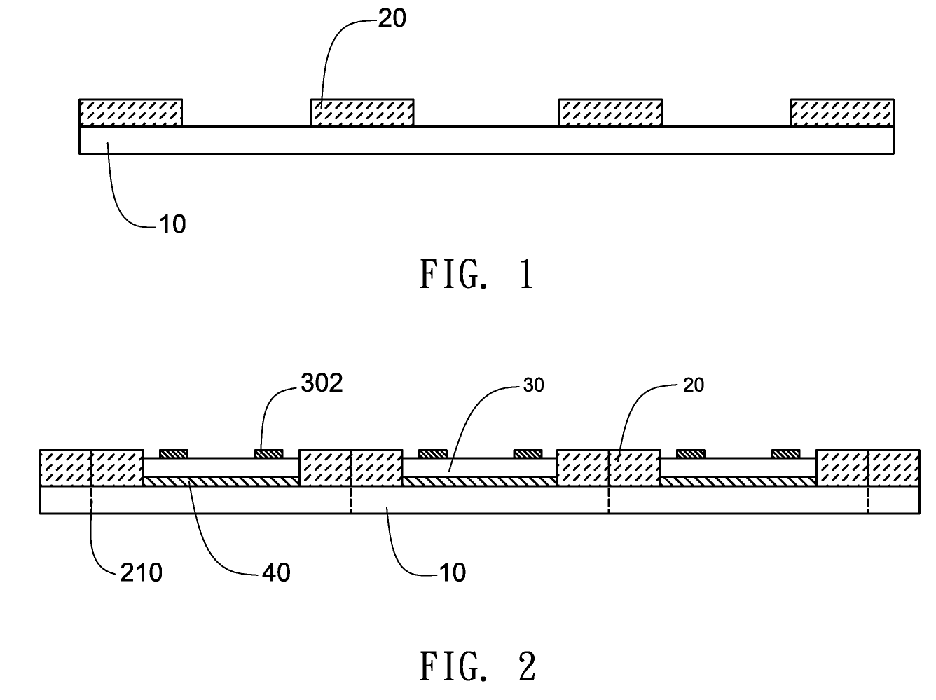

First of all, a wafer (not shown) is provided herein and the wafer includes a plurality of dice (not shown). There are a lot of pads (not shown) in each of the die. FIG. 1 is a sectional view showing that the package structure on the substrate. As shown in FIG. 1, a package structure 20 is formed on the carrier board 10 and the package structure 20 includes a plurality of openings 202 and those openings are used to a portion of the surface of the carrier board 10. In the present embodiment, the way of forming the package structure 20 on the carrier board 10 includes the steps: coating a polymer (not shown) on the top surface of the carrier board 10 and utilizing a module device with a plurality of protrusions to laminate the polymer.

Moreover, in the present embodiment, a molding process is used to form the polymer on the carrier board 10. Similarly, a module device with a plurality of protrusions is used to laminate the polymer on the carrier board 10. The polymer, such as Epoxy Molding Compound (EMC), is injected into the space among the molding device and the carrier board 10 and the polymer is able to form on the carrier board 10.

After finishing the procedure of the polymer, a baking process is optionally used to solidify the polymer. Then, a mold releasing process is used to separate the molding device and the polymer. Therefore, a package structure 20 with a plurality of openings 202 formed by a plurality of protrusions is disposed on the surface of the carrier board 10. The openings 202 are used to be the dice disposed positions in the next process.

There is a plurality of sawing lines formed on the surface of the carrier board 20 by a sawing knife, as shown in FIG. 2. In this embodiment, each of the sawing lines is about 0.5˜1 mil and the wide of the sawing line is about 5˜25 mm. In a preferred embodiment, the sawing lines are interlaced to each other and used to be the reference lines when sawing the dice.

Still referring FIG. 2, the wafer was sawed into a plurality of dies 30 and each of the dies 30 is faced up. The pick and place apparatus (not shown) is used to absorb the active surface of each of the die 30 and put the reverse surface of each of the die 30 on the exposed surface of the carrier board 10. The package structure 20 is surrounded at the four sides of each of the die 30. Because the surface of the die includes a plurality of pads 302, the pick and place device is able to distinguish the location of the pads 302 in the active surface of each of the die 30. When the pick and place apparatus is going to put the die 30 on the carrier board 10, each of the die 30 is accurately disposed on the exposed surface of the carrier board 10. When the dies 30 are relocated on the carrier board 10, the die 30 is able to locate on the exposed surface of the carrier board 10. In addition, the openings 202 exposed on the surface of the carrier board 10 is used as the dice location region to relocate those die 30, the reference position of the dice location region can increase the accuracy of relocating the die 30 on the carrier board 10.

Besides, in the present embodiment, the reverse surface of the die 30 further includes an adhesive layer 40. The adhesive layer 40 is used to stick the reverse surface of the die 30 on the exposed surface of the carrier board 10, when the die is disposed on the exposed surface of the carrier board 10. The material of the adhesive layer 40 can be the elastic adhesive material, such as silicone rubber, silicone resin, elastic PU, multi-holes PU, acrylic rubber, die sawing glue, thermal release material or tape.

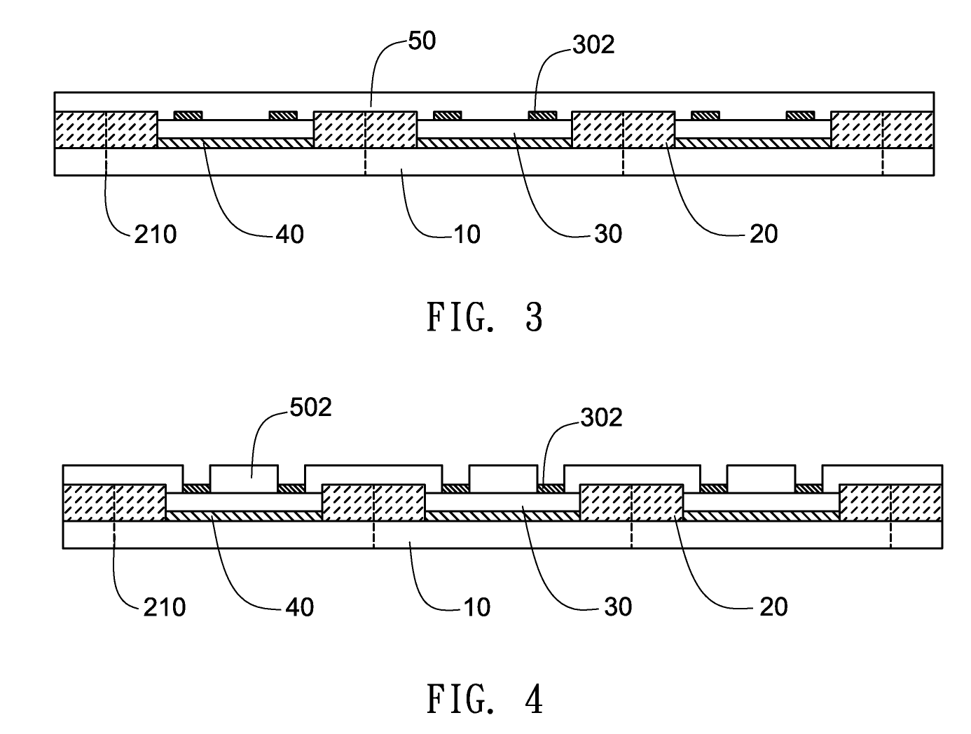

FIG. 3 and FIG. 4 are sectional views showing that a lot of patterned first protective layers are formed on the package structure. As shown in FIG. 3, the first protective layer (not shown) is formed on the package structure 20 and the die 30 and a photoresist layer (not shown) is formed on the first protective layer by a semiconductor process. Then, an etching process is used to remove a portion of first protective layer to form the patterned first protective layer on the package structure 20 and expose a plurality of pads and a plurality of openings on the active surface of the die to show a portion of the surface of the carrier board 10. As shown in FIG. 4, in this embodiment, the material of the first protective layer is paste, B-stage thermal release material or polyimide.

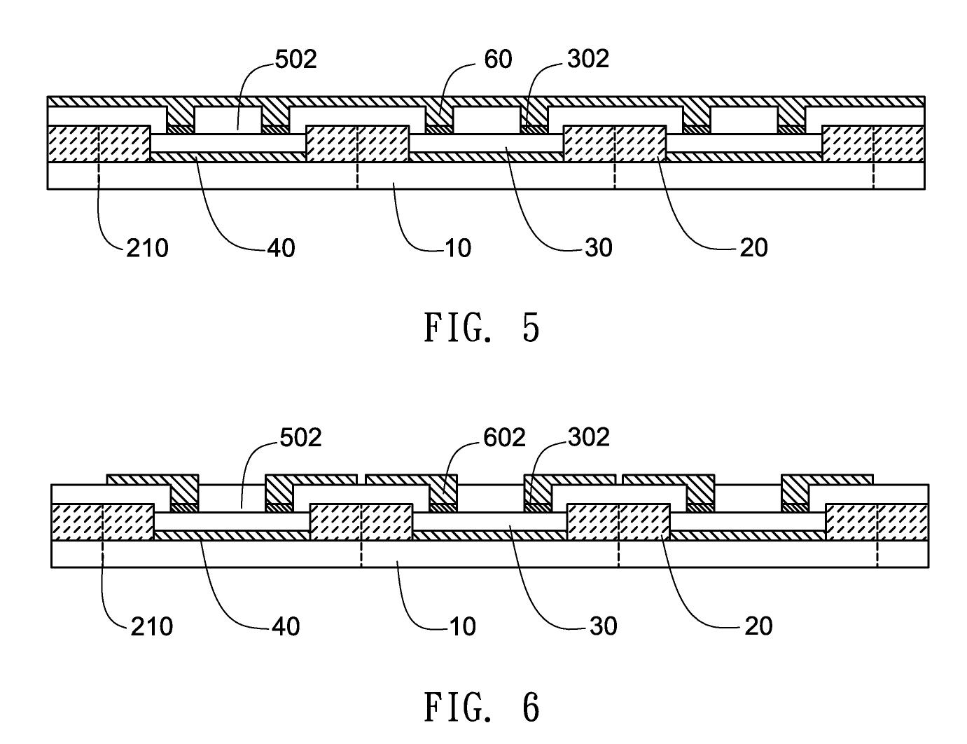

After the positions of the pads 302 of the die 30 are confirmed, the conventional redistribution layer (RDL) is used on the exposed pads 302 of the die 30 to form a plurality of fan-out patterned metal leads 602. One end of each of the patterned metal leads 602 is electrically connected to the pad 302 on the active surface of the chip 30. Another end of the patterned metal leads 602 is formed on the patterned first protective layer 502 by a fan-out format. The steps of forming a plurality of patterned metal leads include: forming a seed layer (not shown) on a portion of the surface of the patterned first protective layer 502; using a electroplated method to form a metal layer 60 on the seed layer and the metal layer 60 is electrically connected to the pads 302 on the active surface of the die 30, as shown in FIG. 5; using a semiconductor method to formed another patterned photoresist layer (not shown) on the metal layer 60; executing a etching step to etch a portion of the metal layer 60 on the patterned first protective layer to form a plurality of fan-out patterned metal leads 602. One end of the fan-out patterned metal leads is electrically connected to the pad 302 on the active surface of the die 30 and the other end of the metal leads 602 is a extended fan-out structure and covered on the patterned first protective layer 502, as shown in FIG. 6.

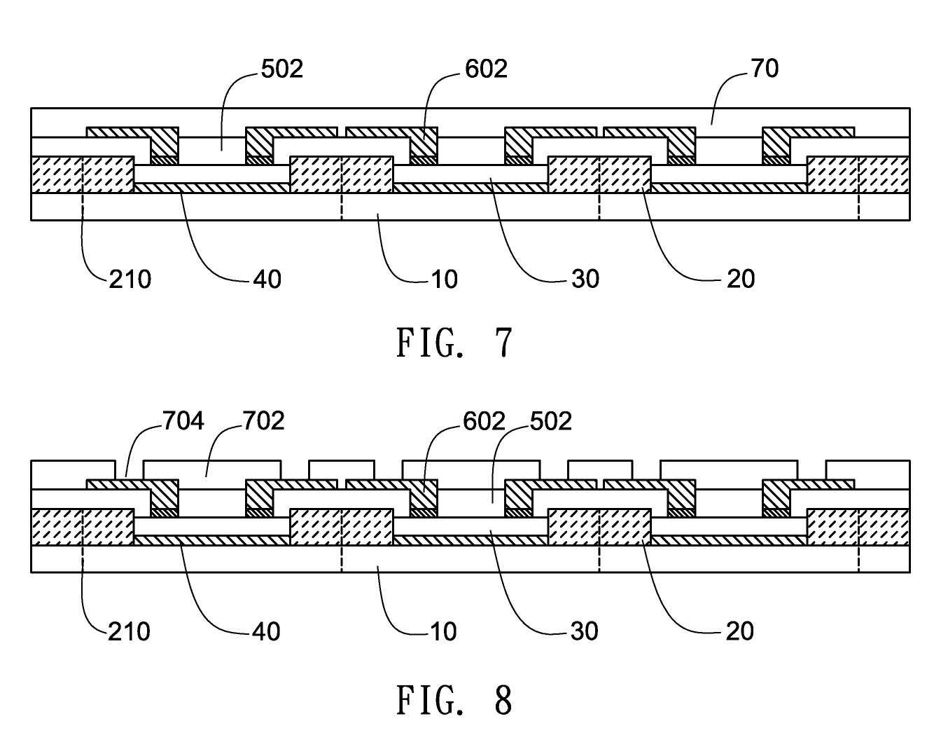

FIG. 7 and FIG. 8 are views showing that a lot of patterned second protective layers are formed on the fan-out patterned metal leads. As shown in FIG. 7, by a semiconductor procedure, the second protective layer 70 is formed to cover the fan-out patterned metal leads 602. Another patterned photoresist layer (not shown) is formed on the second protective layer 70. Then, an etching process is used to remove a portion of the second protective layer 70 to form a plurality of patterned second protective layer 702. There are a lot of openings formed on the surface extended from the active surface of the die 30 corresponding to the patterned metal leads 602. Thus, the surface in each of the fan-out patterned metal leads 602 is exposed, as shown in FIG. 8. In the present embodiment, the material of the second protective layer is paste, B-stage thermal release material or polyimide.

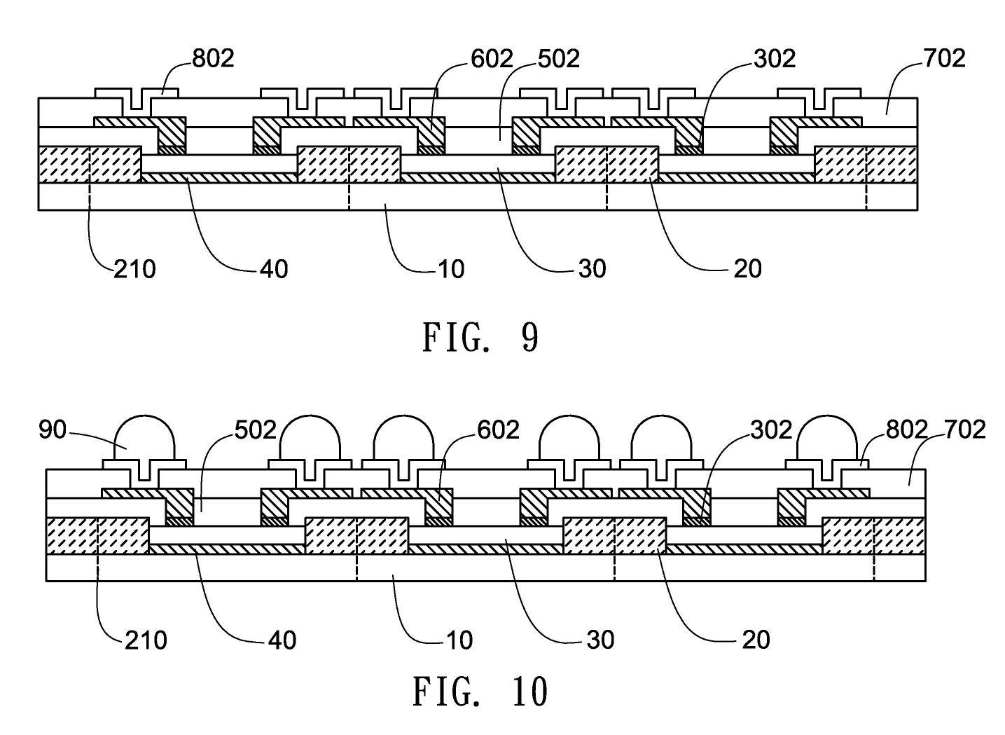

Now referring to FIG. 9, it is a sectional view showing that a lot of patterned UBM layer are formed on the surface on the other end of the fan-out patterned metal leads. As shown in FIG. 9, a UBM layer (not shown) is formed on the exposed surface of the other end of the fan-out patterned metal lead 602 by sputtering method. By using a etching step, a portion of the UBM layer is removed to form a patterned UBM layer 802 on the exposed surface of each of the fan-out patterned metal leads 602 extended from the die. The patterned UBM layer 802 is electrically connected to the patterned metal leads 602. In the present embodiment, the material of the UBM layer 802 is Ti/Ni or Ti/W.

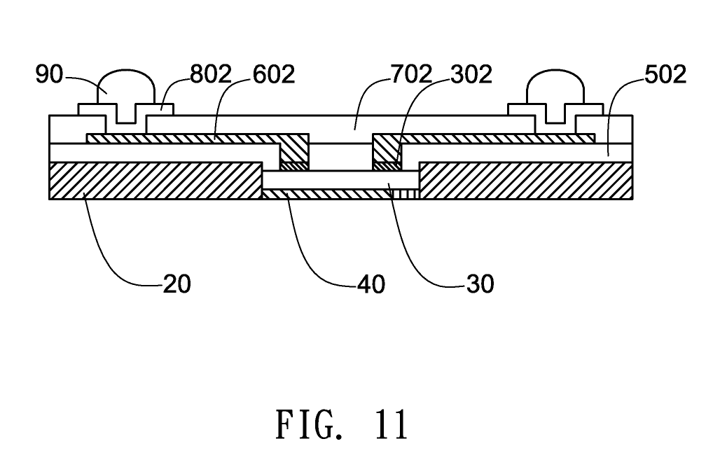

Finally, there are a lot of conductive elements 90 formed on the UBM layer 802. The conductive elements 90 are used to electrically connect the patterned UBM layers 802 and the patterned metal leads 602, as shown in FIG. 10. The conductive element 90 is a metal bump or a solder ball. Then, the carrier board 10 is removed and the package structure is doing the final sawing process. In the present embodiment, a signal die is used to be a sawing unit and each of the dice package structure is formed, as shown in FIG. 11.

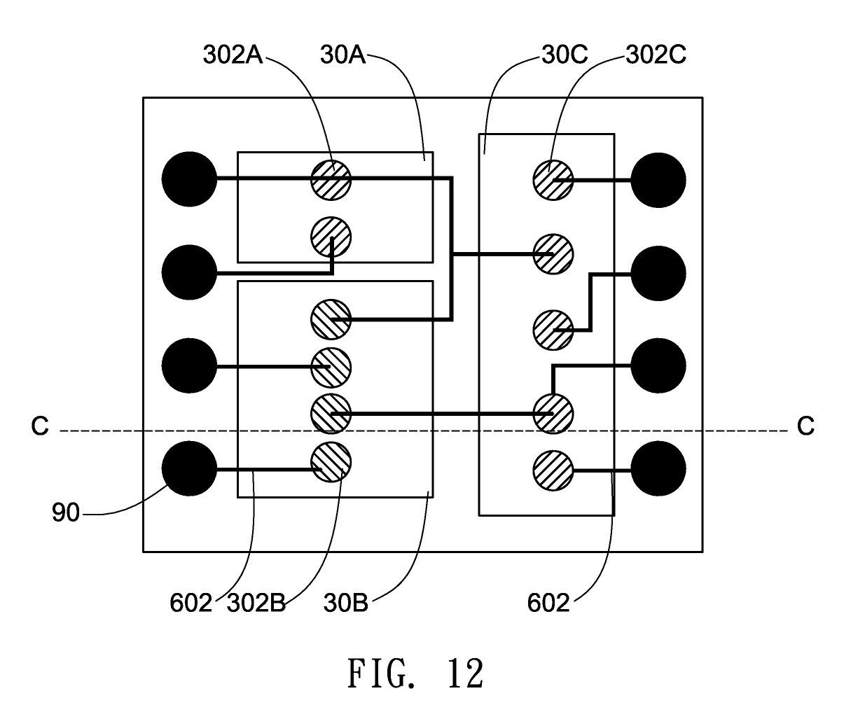

Now, FIG. 12 is a top view showing that a plurality of dice with different functions and different sizes to formed a system-in-package (SIP). In the present embodiment, the dice are with different size and different function, such as microprocessor means 30A, memory means 30B and/or memory controller means 30C. The active surface on each of the dice 30A, 30B and 30C includes a plurality of pads 302A, 302B and 302C. There are a plurality of metal leads 602 formed on the pads 302A, 302B and 302C. The metal leads 602 are serially or parallelly electrically connect the dice 30A, 30B and 30C and the conductive elements 90.

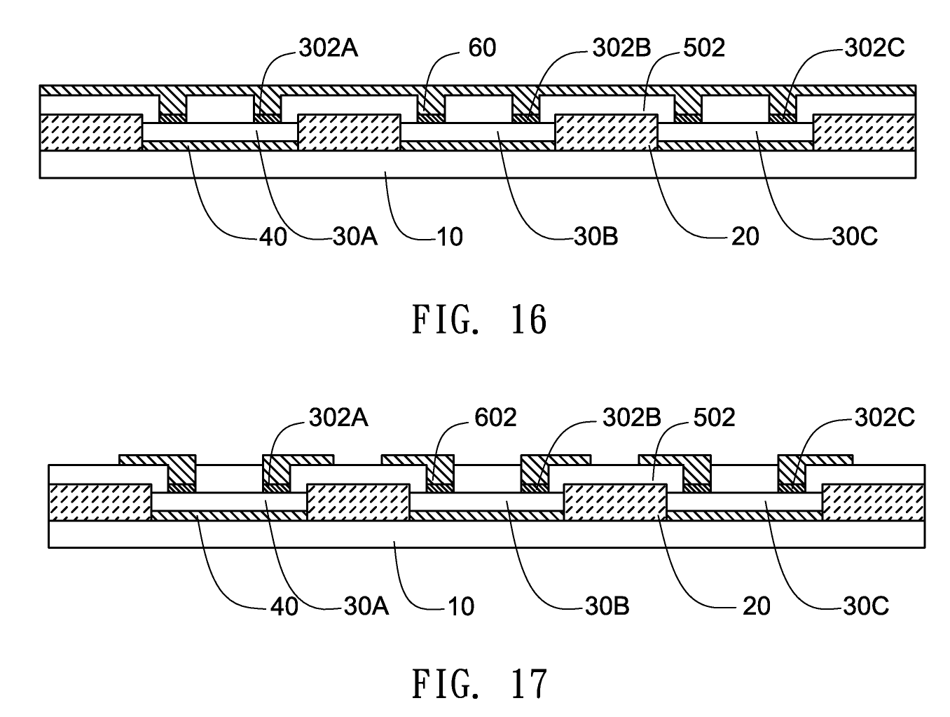

FIG. 13 through FIG. 21 are views showing that the system in package structure. FIG. 13 is a view showing that the dice with different sizes and different functions are disposed on the carrier board with package structure. As shown in FIG. 13, the package structure 20 with openings 202 is formed on the carrier board 10. The sizes of the openings 202 are corresponding to the sizes of the dice 30A, 30B and 30C. Then, the wafer with different dice is sawed to form a plurality of dice 30A, 30B and 30C and the active surface of the dice 30A, 30B and 30C is faced up; using a pick and place device (not shown) to pick up the dice 30A, 30B and 30C from the active surface of the dice 30A, 30B and 30C and the reverse surface of the dice 30A, 30B and 30C is disposed on the exposed surface of a portion of the carrier board 10. Because the active surface of the dice 30A, 30B and 30C includes a plurality of pads 302A, 302B and 302C, the pick and place device is able to determine the position of the pads 302A, 302B and 302C of the dice 30A, 30B and 30C. When the pick and place device will put the dice 30A, 30B and 30C on the carrier board 10, the dice 30A, 30B and 30C are able to dispose on the exposed surface of the carrier board 10. When the dice 30A, 30B and 30C are relocated on the carrier board 10, the dice 30A, 30B and 30C are able to locate at the desired positions on the carrier board 10. Besides, the openings 202 of the package structure 20 on the exposed surface of the carrier board are used to be the positions where the dice 30A, 30B and 30C are located, so the accuracy of relocating the dice is increased.

In addition, in the present embodiment, each of the dice 30A, 30B and 30C includes a reverse surface and there is an adhesive layer 40 on the reverse surface. The adhesive layer 40 is used to stick the reverse surface of the dice 30A, 30B and 30C on the exposed surface of the carrier board 10 when the dice 30A, 30B and 30C are disposed on the exposed surface of the carrier board 10. In the present embodiment, the material of the adhesive layer 40 is elastic adhesive material, such as silicon rubber, silicon resin, elastic PU, porous PU, acrylic rubber, die sawing glue, thermal release material or tape.

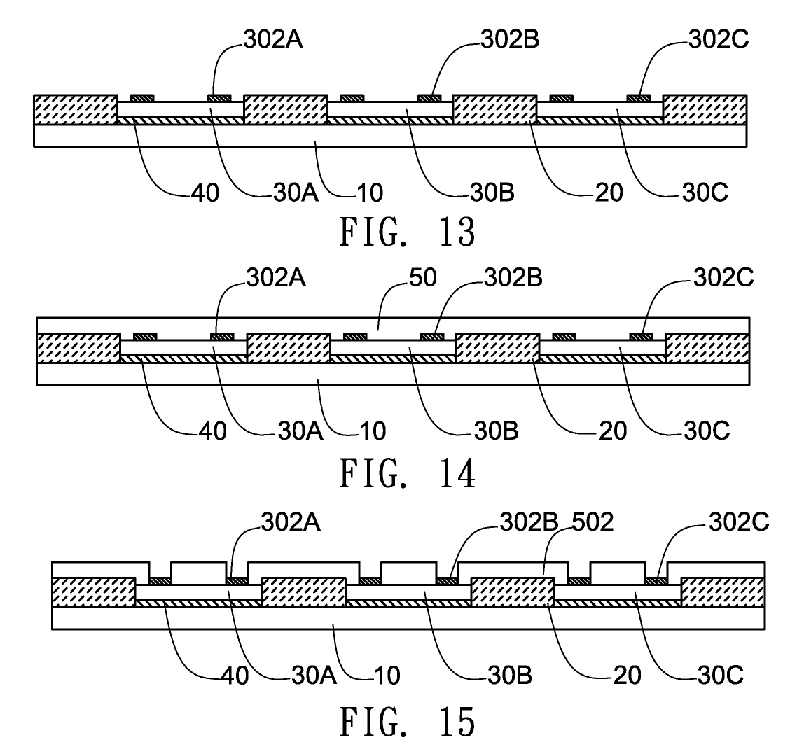

FIGS. 14 and 15 are sectional views showing that a lot of patterned first protective layers are formed. The forming method is: forming a first protective layer 50 on the package structure 20 and the active surface of the dice 30A, 30B and 30C, as shown in FIG. 14; utilizing a semiconductor process to form a photoresist layer (not shown) on the first protective layer 50; etching a portion of first protective layer 50 to form a plurality of patterned first protective layer 502 on the package structure 20 and expose the active surface of the dice 30A, 30B and 30C, as shown in FIG. 15. The material of the first protective layer 50 is paste, B-stage thermal solid glue or polyimide.

After the positions of the pads 302A, 302B and 302C of the dice 30A, 30B and 30C are confirmed, the conventional redistribution layer (RDL) is used to form a plurality of fan-out patterned metal leads 602 on the pads 302A, 302B and 302C. One of each of the patterned metal leads 602 is electrically connected to the pads 302A, 302B and 302C. The other end of some of the patterned metal leads 602 is formed on the patterned first protective layer 502 by a fan-out method. The patterned metal leads 602 is formed by the following steps: forming a seed layer (not shown) on the surface of the patterned first protective layer 502 and the pads 302A, 302B and 302C; electroplating a metal layer 60 on the seed layer; forming another patterned photoresist layer (not shown) on the metal layer; etching a portion of the metal layer 60 on the patterned first protective layer 602, and one end of some of the fan-out patterned metal layer 60 is electrically connected to the pads 302A, 302B and 302C. The other end of some of the patterned metal leads 602 is covered on the patterned first protective layer 502, as shown in FIG. 17.

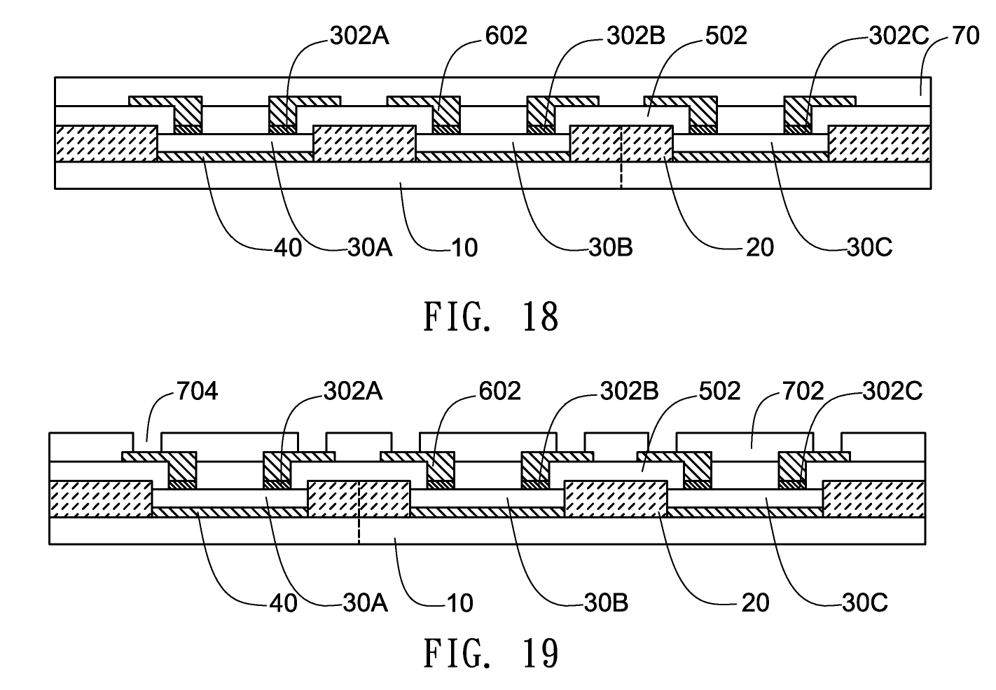

FIGS. 18 and 19 are views showing that a lot of patterned second protective layer are formed on the fan-out patterned metal leads. The forming method includes the following steps: utilizing a semiconductor process to let the second protective layer 70 cover on some of the patterned metal leads 602 and some of the patterned first protective layer 502, as shown in FIG. 18; forming a patterned photoresist layer (not shown) in the second protective layer 70; etching a portion of the second protective layer 70 to form a plurality of patterned second protective layer 702 and forming a plurality of openings on the surface extended from the active surface of the dice 30A, 30B and 30C and corresponding to each of the patterned metal leads 602, the openings are used to expose another surface of the other end of the fan-out patterned meal leads 602. The material of the second protective layer 70 is paste, B-stage thermal solid glue or polyimide.

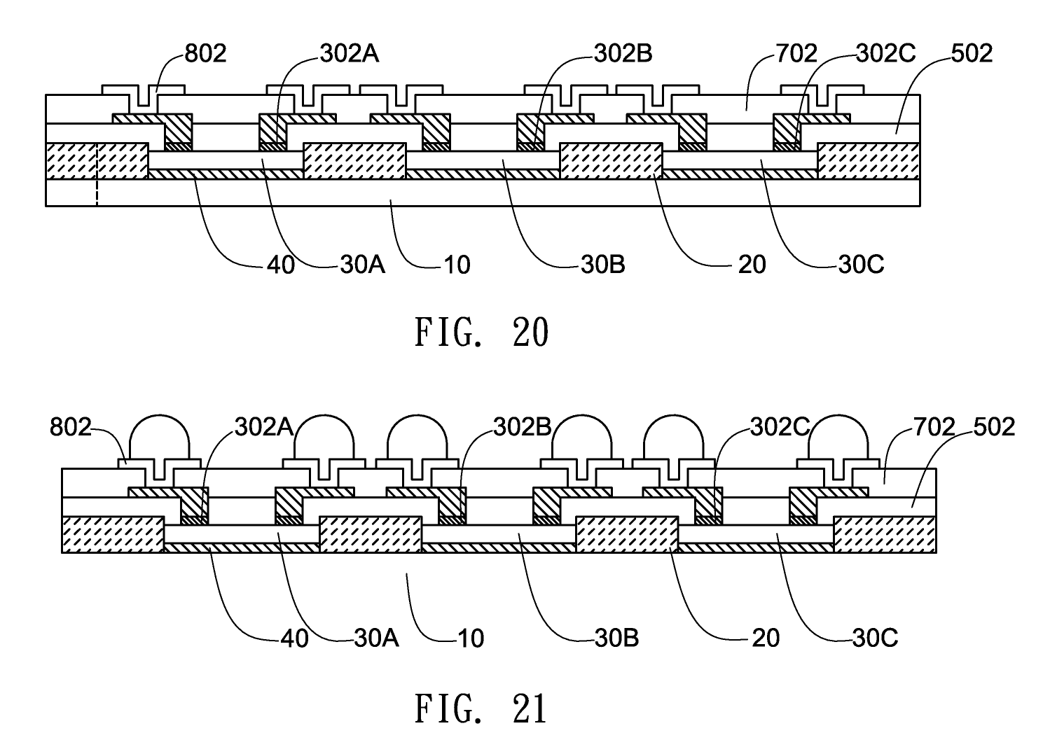

FIG. 20 is a view showing that a lot of patterned UBM layers are formed on the surface of the other end of the metal leads. As shown in FIG. 20, a UBM layer (not shown) is formed on the exposed surface of the other end of the patterned metal leads 602 by a sputtering method. a patterned photoresist layer (not shown) is formed on the UBM layer by a semiconductor process. A portion of the UBM layers are removed by etching to form a plurality of patterned UBM layer 802 on the exposed surface of the metal leads 602 and the patterned UBM layer 802 is electrically connected to the metal lead 602. In the present embodiment, the material of the UBM layer 802 is Ti/Ni or Ti/W.

Subsequently, a plurality of conductive elements are formed on each of the patterned UBM layer 802 to be the connective point of the dice 30A, 30B and 30C. The conductive element is metal bump or solder ball. The conductive element is electrically connected to the metal leads 602 by the patterned UBM layer 802. Then, the carrier board 10 is removed to finish the package structure, as shown in FIG. 21.

Although specific embodiments have been illustrated and described, it will be appreciated by those skilled in the art that various modifications may be made without departing from the scope of the present invention, which is intended to be limited solely by the appended claims.

What is claimed is:

1. A die rearrangement package method, comprising:
providing a carrier board, and said carrier board includes a top surface and a reverse surface;
forming an encapsulated structure on said top surface of said carrier board and said encapsulated structure includes an opening formed on said top surface of said carrier board and exposed on a portion of said top surface of said carrier board;
adhering a die on a portion of said exposed top surface of said carrier board and an active surface of said die is faced up, and said active surface includes a plurality of pads, a reverse surface of said die is adhered on a portion of said exposed top surface of said carrier board by an adhesive layer;
forming a patterned first protective layer on said encapsulated structure and said patterned first protective layer is covered on said active surface of said die and exposes a portion of said top surface of said carrier board;
forming a plurality of fan-out patterned metal leads, and one end of said metal lead is electrically connected to said pads on said active surface of said die;
forming a patterned second protective layer, and said patterned second protective layer is covered on said fan-out patterned metal lead and exposes a portion of fan-out surface extended from the edge of said active surface of said die;
forming a plurality of patterned UBM layer on said portion of fan-out surface extended from the edge of said active surface of said die and said patterned UBM layer is electrically connected to said metal lead;
forming a plurality of conductive elements formed on said patterned UBM layer and electrically connected to said metal lead by said patterned UBM layer; and
removing said carrier board to form a die package structure.

2. The package method of claim 1, wherein the material of said carrier board is selected from the group consisting of: glass, quartz and circuit board.

3. The package method of claim 1, wherein the material of said carrier board is metal substrate.

4. The package method of claim 1, wherein the material of said patterned first protective layer and said patterned second protective layer is selected from the group consisting of: polyimide, paste and B-stage.

5. The package method claim 1, wherein said step for forming said fan-out patterned metal lead includes:
forming a seeding layer on a portion of said surface of said patterned first protective layer and said pads of said active surface of said die;
electroplating a metal layer on said seeding layer and said metal layer is electrically connected to said pads of said active surface of said die;
forming a patterned photoresist layer on said metal layer; and
etching a portion of said metal layer to remove a portion of said metal layer on said patterned first protective layer to form said fan-out patterned metal lead, and another end of said fan-out patterned metal lead is an extended fan-out structure and covered on said patterned first protective layer.

6. The package method of claim 1, wherein the material of said UBM layer is Ti/Ni or Ti/W.

7. A die rearrangement package method, comprising:
providing a carrier board, and said carrier board includes a top surface and a reverse surface;
forming an encapsulated structure on said top surface of said carrier board and said encapsulated structure includes a plurality of openings formed on said top surface of said carrier board and exposed on a portion of said top surface of said carrier board;
adhering a plurality of dice on a portion of said exposed top surface of said carrier board and an active surface of said dice are faced up, and said active surface includes a plurality of pads, a reverse surface of each of said dice is adhered on a portion of said exposed top surface of said carrier board by an adhesive layer;
forming a patterned first protective layer on said encapsulated structure and said patterned first protective layer is covered on said active surface of said die and exposes a portion of said top surface of said carrier board;
forming a plurality of fan-out patterned metal leads, and one end of said metal lead is electrically connected to said pads on said active surface of said die;
forming a patterned second protective layer, and said patterned second protective layer is covered on said fan-out patterned metal lead and exposes a portion of fan-out surface extended from the edge of said active surface of said die;
forming a plurality of patterned UBM layer on said portion of fan-out surface extended from the edge of said active surface of said die and said patterned UBM layer is electrically connected to said metal lead;
forming a plurality of conductive elements formed on said patterned UBM layer and electrically connected to said metal lead by said patterned UBM layer; and
removing said carrier board to form a die package structure.

8. The package method of claim 7, wherein said dice are dice with the same functions and the same size.

9. The package method of claim 7, wherein said die is die with different functions and different size.

10. The package method of claim 7, wherein said die are micro processors, memory means and memory controller means.

11. The package method claim 7, wherein said step for forming said fan-out patterned metal lead includes:
forming a seeding layer on a portion of said surface of said patterned first protective layer and said pads of said active surface of said die;
electroplating a metal layer on said seeding layer and said metal layer is electrically connected to said pads of said active surface of said die;
forming a patterned photoresist layer on said metal layer; and
etching a portion of said metal layer to remove a portion of said metal layer on said patterned first protective layer to form said fan-out patterned metal lead, and another end of said fan-out patterned metal lead is an extended fan-out structure and covered on said patterned first protective layer.

12. The package method of claim 7, wherein the material of said UBM layer is Ti/Ni or Ti/W.

13. A die including an active surface with a plurality of pads and a reverse surface with an adhesive layer;
a die including an active surface with a plurality of pads and a reverse surface with an adhesive layer;
an encapsulated structure, which is covered around four sides of said die to expose said active surface and said reverse surface of said die;
a patterned first protective layer, which is formed on one surface of said encapsulated structure and covered on said active surface of said die, and said pads are exposed;
a plurality of fan-out patterned metal lead, and one end of said metal lead is electrically connected to said pads on said active surface of said die;
a patterned second protective layer covered over said fan-out patterned metal lead and exposing a portion of fan-out surface extended from the edge of said active surface of said die;
a plurality of patterned UBM layer formed on said portion of fan-out surface extended from the edge of said active surface of said die;
a plurality of conductive elements formed on said patterned UBM layer and electrically connected to said metal lead by said patterned UBM layer.

14. The package structure of claim 13, wherein said encapsulated structure Epoxy Molding Compound (EMC).

15. The package structure of claim 13, wherein the material of said patterned first protective layer and said patterned second protective layer is selected from the group consisting of: polyimide, paste and B-stage.

16. The package structure of claim 13, wherein the material of said UBM layer is Ti/Ni or Ti/W.

17. A die including an active surface with a plurality of pads and a reverse surface with an adhesive layer;
a plurality of dies and each of said dice includes an active surface with a plurality of pads and a reverse surface with an adhesive layer;
an encapsulated structure, which is covered around four sides of said dice to expose said active surface and said reverse surface of said dies;
a plurality of patterned first protective layers, which are formed on one surface of said encapsulated structure and covered on said active surface of said dies, and said pads are exposed;
a plurality of fan-out patterned metal lead, and one end of said metal lead is electrically connected to said pads on said active surface of said die;
a plurality of patterned second protective layer covered over said fan-out patterned metal lead and exposing a portion of fan-out surface extended from the edge of said active surface of said dies;
a plurality of patterned UBM layer formed on said portion of fan-out surface extended from the edge of said active surface of said die;
a plurality of conductive elements formed on said patterned UBM layer and electrically connected to said metal lead by said patterned UBM layer.

18. The package structure of claim 17, wherein said die is die with the same functions and the same size.

19. The package structure of claim 17, wherein said die is die with different functions and different size.

20. The package structure of claim 17, wherein said die is micro processors, memory devices and memory controlling devices.
